(19) United States
(12) Patent Application Publication
(10) Pub. No.: US 2016/0160353 A1
(43) Pub. Date: Jun. 9, 2016

(54) INTERLOCKED PLATED POLYMERS

(71) Applicant: UNITED TECHNOLOGIES CORPORATION, Farmington, CT (US)

(72) Inventors: Michael S. Miarecki, Enfield, CT (US); Charles R. Watson, Windsor, CT (US); Grant O. Cook, Spring, TX (US); Joseph Parkos, East Haddam, CT (US)

(21) Appl. No.: 14/903,861

(22) PCT Filed: Jul. 9, 2014
(86) PCT No.: PCT/US2014/045921

§ 371 Date: Jan. 8, 2016

Related U.S. Application Data
(60) Provisional application No. 61/844,108, filed on Jul. 9, 2013.

(51) Int. Cl. C23C 18/16; C25D 3/02

(52) U.S. Cl. CPC C23C 18/1633; C25D 3/02

(57) ABSTRACT

A plated polymer component is disclosed. The plated polymer component may comprise a polymer substrate having an outer surface, a metal plating attached to the outer surface of the polymer substrate, and at least one interlocking feature connecting the polymer substrate and the metal plating. The interlocking feature may improve the interfacial bond strength between the polymer substrate and the metal plating.

### CROSS-REFERENCE TO RELATED APPLICATIONS

This application claims priority under 35 U.S.C. §119(e) to U.S. Provisional Patent Application Ser. No. 61/844,108 filed on Jul. 9, 2013.

### FIELD OF THE DISCLOSURE

The present disclosure generally relates to metal-plated polymer components having improved physical and mechanical properties. More specifically, this disclosure relates to metal-plated polymer components having improved interfacial bond strengths.

### BACKGROUND

Metal-plated polymer components consist of a polymer substrate coated with a metal plating. These components are lightweight and, by virtue of the metal plating, exhibit markedly enhanced structural strength and capability over the structural strength and capability of the polymer substrate alone. These properties have made them attractive for component fabrication in many industries such as aerospace, automotive, and military equipment industries, where high-strength and lightweight materials are desired. For example, metal-plated polymer components continue to be explored for use in gas turbine engine applications to reduce the overall weight of the engine and improve engine efficiency and provide fuel savings. However, the strength and performance characteristics of metal-plated polymer materials may be dependent upon the integrity of the interfacial bond between the metal plating and the underlying polymer substrate. Even though the surface of the polymer substrate may be etched or abraded to promote the adhesion of metals to the polymer surface and to increase the surface area of contact between the metal plating layer and the polymer substrate, the interfacial bond strength between the metal plating and the polymer substrate may be the structurally weak point of metal-plated polymer structures. As such, the metal plating layers may become disengaged from polymer substrate surfaces which could lead to part failure in some circumstances.

The interfacial bond strength between the metal plating and the underlying polymer substrate may be compromised upon exposure to high temperatures, such as those experienced during some high-temperature engine operations. If metal-plated polymers are exposed to temperatures over a critical temperature or a sufficient amount of thermal fatigue (thermal cycling or applied loads at elevated temperatures) during operation, the interfacial bond between the metal plating and the polymer substrate may be at least partially degraded, which may lead to structural break-down of the component and possible in-service failure. Unfortunately, brief or minor exposures of metal-plated polymer components to structurally-compromising temperatures may go largely undetected in many circumstances, as the weakening of the bond between the metal-plating and the underlying polymer substrate may be difficult to detect. To provide performance characteristics necessary for the safe use of metal-plated polymer components in gas turbine engines and other applications, enhancements are needed to improve the interfacial bond strengths of metal-plated polymer components.

Clearly, a system is needed to improve the mechanical strength of the interfacial bond between metal platings and polymer surfaces in plated polymer components.

### SUMMARY OF THE DISCLOSURE

In accordance with one aspect of the present disclosure, a plated polymer component is disclosed. The plated polymer component may comprise a polymer substrate having an outer surface and a metal plating attached to the outer surface of the polymer substrate. The plated polymer component may further comprise at least one interlocking feature connecting the polymer substrate and the metal plating.

In another refinement, the at least one interlocking feature may comprise and interlocking aperture formed on the outer surface of the polymer substrate that is filled with a material of the metal plating.

In another refinement, the plated polymer component may comprise a plurality of the at least one interlocking features.

In another refinement, the interlocking aperture may be formed on the outer surface of the polymer substrate by a method selected from the group consisting of additive manufacturing, injection molding, and machining.

In another refinement, the at least one interlocking aperture may comprise a crevice formed on the outer surface of the polymer substrate that is filled with a material of the metal plating.

In another refinement, the crevice may be formed on the outer surface of the polymer substrate by micro-knurling.

In another refinement, the at least one interlocking feature may comprise at least one interlocking hole extending through a body of the polymer substrate, and the at least one interlocking hole may include a hole extending through the body of the polymer substrate that is plated along a wall of the hole with the metal plating.

In another refinement, the hole may be formed through the body of the polymer substrate by a method selected from the group consisting of injection molding, additive manufacturing, machining, drilling, and etching.

In another refinement, the at least one interlocking hole may be filled with a filling agent.

In accordance with another aspect of the present disclosure, a plated polymer component is disclosed. The plated polymer component may comprise a polymer substrate having at least one exposed surface, and a metal plating deposited on the at least one exposed surface of the polymer substrate. The plated polymer component may further comprise at least one interlocking hole extending through a body of the polymer substrate, and the at least one interlocking hole may include a hole extending through the body of the polymer substrate that is plated along a wall of the hole with the metal plating.

In another refinement, the metal plating may be plated on the wall of the hole by electrolytic deposition.

In another refinement, the hole may have a diameter of at least about 1.6 mm.

In another refinement, the metal plating may be plated on the wall of the hole by electroless deposition.

In another refinement, the hole may have a diameter of at least about 0.8 mm.

In another refinement, the at least one interlocking hole may be filled with a filling agent.

In another refinement, the filling agent may be selected from a group consisting of an epoxy material, an epoxy material containing a filler metal, a low-melting alloy, and one or more wires.

In accordance with another aspect of the present disclosure, a plated polymer component is disclosed. The plated polymer component may comprise a polymer substrate having an outer surface, and a metal plating attached to the outer surface of the polymer substrate. The plated polymer component may further comprise a plurality of interlocking features at an interface between the metal plating and the polymer substrate. Each of the plurality of interlocking features may consist of an interlocking aperture formed on the outer surface of the polymer substrate that is filled with a material of the metal plating.

In another refinement, the interlocking aperture may be formed on the outer surface of the polymer substrate by a method selected from the group consisting of additive manufacturing, injection molding, and machining.

In another refinement, the interlocking aperture may have a depth of at least about 0.005 mm.

In another refinement, at least one of the plurality of interlocking apertures may comprise a crevice formed on the outer surface of the substrate that is filled with a material of the metal plating.

These and other aspects and features of the present disclosure will be more readily understood when read in conjunction with the accompanying drawings.

### BRIEF DESCRIPTION OF THE DRAWINGS

FIG. 1 is a front view of a plated polymer component having a polymer substrate and a metal plating, constructed in accordance with the present disclosure.

FIG. 2 is cross-sectional view of the plated polymer component of FIG. 1 taken along the line 2-2 of FIG. 1, constructed in accordance with the present disclosure.

FIG. 3 is a side cross-sectional view of a polymer substrate similar to FIG. 2 but having crevices on its outer surface, constructed in accordance with the present disclosure.

FIG. 4 is a flow chart diagram illustrating steps involved in the fabrication of the plated polymer component of FIGS. 1 and 2, in accordance with a method of the present disclosure.

FIG. 5 is a front view of an interlocked plated polymer component constructed in accordance with the present disclosure.

FIG. 6 is a cross-sectional view of the interlocked plated polymer component of FIG. 5 taken along the line 6-6 of FIG. 5, constructed in accordance with the present disclosure.

FIG. 7 is a cross-sectional view, similar to FIG. 6, but having a filling agent in the interlocking holes.

FIG. 8 is a cross-sectional view schematically illustrating the formation of the interlocked plated polymer component of FIG. 6, in accordance with a method of the present disclosure.

FIG. 9 is a flow chart diagram, illustrating the steps involved in the formation of the interlocked plated polymer component, in accordance with a method of the present disclosure.

It should be understood that the drawings are not necessarily drawn to scale and that the disclosed embodiments are sometimes illustrated schematically and in partial views. It is to be further appreciated that the following detailed description is merely exemplary in nature and is not intended to limit the invention or the application and uses thereof. In this regard, it is to be additionally appreciated that the described embodiment is not limited to use with specific applications. Hence, although the present disclosure is, for convenience of explanation, depicted and described as certain illustrative embodiments, it will be appreciated that it can be implemented in various other types of embodiments and in various other systems and environments.

### DETAILED DESCRIPTION

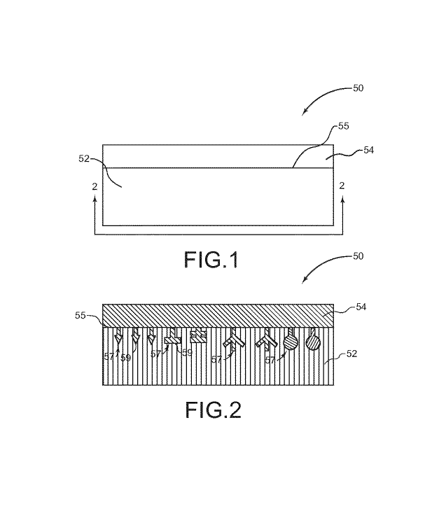

Referring now to FIG. 1, a plated polymer component 50 is shown. It is noted that the planar structure of the plated polymer component 50 is exemplary and, in practice, may have any structure suitable for its application, whether simple or complex. This may include structures having curved surfaces and/or internal passages or pores, for example. The plated polymer 50 may consist of a polymer substrate 52 having one or more metal platings 54 attached to one or more of its outer surfaces 55, as shown. The thickness of the metal plating 54 may be in the range of about 0.001 inches (0.0254 mm) to about 0.050 inches (1.27 mm), but other metal plating thicknesses may also apply. The metal plating 54 may consist of one or metals selected from nickel, cobalt, copper, iron, gold, silver, palladium, rhodium, chromium, zinc, tin, cadmium, and alloys with any of the foregoing elements comprising at least 50 wt. % of the alloy, and combinations thereof.

The polymer substrate 52 may be formed from a thermoplastic or thermoset material. Suitable thermoplastic materials may include, but are not limited to, polyetherimide (PEI), thermoplastic polyimide, polyether ether ketone (PEEK), polyether ketone ketone (PEKK), polysulfone, polyamide, polyphenylene sulfide, polyester, polyimide, and combinations thereof. Suitable thermoset materials may include, but are not limited to, condensation polyimides, addition polyimides, epoxy cured with aliphatic and/or aromatic amines and/or anhydrides, cyanate esters, phenolics, polyesters, polybenzoxazine, polyurethanes, polyacrylates, polymethacrylates, silicones (thermoset), and combinations thereof. Optionally, the polymeric material of the polymer substrate 52 may be structurally reinforced with materials that may include carbon, metal, or glass.

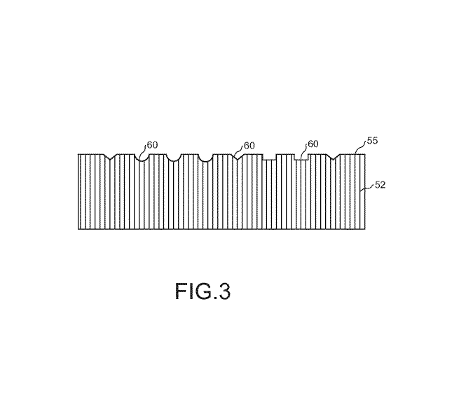

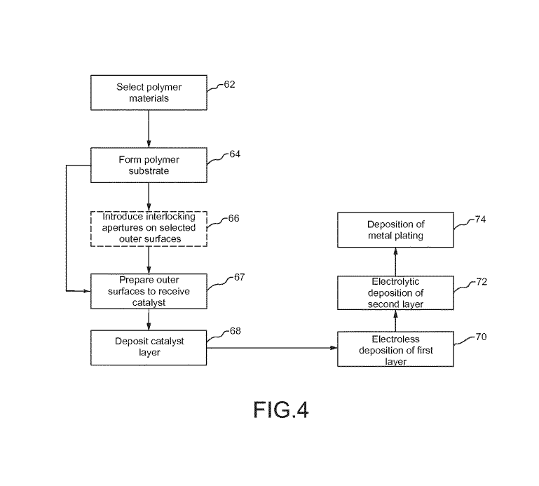

At or near the interface of the metal plating 54 and the polymer substrate 52 may be one or more interlocking features 57 which may behave as mechanical fasters between the metal plating 54 and the polymer substrate 52, as shown in FIG. 2. Each of the interlocking features 57 may consist of an interlocking aperture 59 formed on the outer surface of the polymer substrate 52 filled with the metal material of the plating 54. The interlocking features 57 may enhance the strength of the interfacial bond between the metal plating 54 and the polymer substrate 52 by about two times or more compared with plated polymer structures that lack such interlocking features. In particular, the interlocking features 57 may resist mechanical disengagement of the metal plating 54 from the polymer substrate 52, as disengagement would require cohesive failure of the polymer substrate 52 and/or the metal plating 54. Moreover, the interlocking features 57 may substantially increase the surface area of contact between the metal plating 54 and the outer surface 55 of the polymer substrate 52 as compared to traditional etching or abrasion processes. In this regard, the interlocking features 57 may also eliminate or reduce the need for chemical etching or mechanical roughening of the outer surface(s) 55 of the polymer substrate 52 normally required for deposition of the metal plating 54 (see FIG. 4 and further details below). The interlocking features 57 may also eliminate the need for the use of chemical adhesion promoters at the interface 55 between the metal plating 54 and the polymer substrate 52.

The interlocking apertures 59 may have one or more various shapes including, but not limited to, upside-down “T” shapes, arrow shapes, double “T” shapes, tri-pod shapes, and/or upside-down street-sign shapes, as shown, and may be introduced into the outer surface by additive manufacturing, injection molding, or machining (see further details below). Depending on the performance requirements of the plated polymer component 50 as well as other considerations, the interlocking apertures 59 may be evenly distributed across the outer surface 55 or may be localized to specific areas of the outer surface 55 requiring a stronger attachment of the metal plating 54. In addition, they may be present on the outer surface 55 in a pre-determined pattern or in a random pattern. The minimum depth of the interlocking apertures 59 may be about 0.0002 inches (about 0.005 mm) and the minimum spacing between the interlocking apertures 59 may be about 0.0002 inches (about 0.005 mm) according to the reproducibility of current polymer fabrication processes, but other aperture depths and spacings may also suffice depending on the manufacturing method used. The diameter (or width) of the interlocking apertures 59 may be at least wide enough to allow the deposition of the metal plating 54 within the interlocking apertures 59. More specifically, the diameters of the interlocking apertures 59 may be at least wide enough to permit the deposition of the catalyst used in the metal plating process on the surfaces of the interlocking apertures 59 (see further details below).

As an alternative arrangement, the outer surface 55 of the polymer substrate 52 may have one or more crevices 60 which may lack a mechanical interlocking ability but may increase the surface area of contact between the metal plating 54 and the polymer substrate 52 (see FIG. 3). Similar to the interlocking apertures 59, the crevices 60 may also eliminate or reduce the need for polymer surface etching or abrasion as well as the use of chemical adhesion promoters or activators during the metal plating process. The crevices 60 may have one or more various shapes such as, but not limited to circular shapes, elliptical shapes, triangular shapes, and/or rectangular shapes, as shown, and may be introduced onto the outer surface 55 by micro-knurling, a technique apparent to those of ordinary skill in the art. The crevices 60 may be evenly distributed in a pre-determined pattern or in a random pattern across the outer surface 55. Alternatively, they may be concentrated in specific areas of the outer surface 55 in a pre-determined or random pattern. Furthermore, the diameters of the crevices 60 may be wide enough to allow the deposition of the palladium or other catalyst used in the metal plating process (see further details below). As yet another alternative arrangement, the outer surface 55 may have a mixture of interlocking apertures 59 and crevices 60.

A series of steps which may be involved in the fabrication of the plated polymer component 50 is illustrated in FIG. 4. According to a first block 62, the thermoplastic or thermoset polymers as well as optional reinforcing fibers for the polymer substrate 52 may be selected. According to a next block 64, the polymer substrate 52 may then be formed in a desired shape by a method apparent to those of ordinary skill in the art such as injection molding, compression molding, blow molding, additive manufacturing (liquid bed, powder bed, deposition processes), or composite layup (autoclave, compression, or liquid molding). The interlocking apertures 59 may be directly introduced into the selected outer surface(s) of the polymer substrate 52 during the molding step by injection molding or additive manufacturing (block 64), or they may be separately introduced after the block 64 by machining according to an optional block 66, as shown. Alternatively, crevices 60 may be introduced onto the selected outer surface(s) 55 of the polymer substrate 52 by micro-knurling during the optional block 66. In this regard, it is noted that the crevices 60 may be introduced onto the outer surface(s) 55 instead of or in combination with the interlocking apertures 57.

Following the block 66, several steps may be performed (blocks 67, 68, 70, 72, and 74) to deposit the metal plating 54 on selected outer surfaces 55 of the polymer substrate. According to a block 67, one or more outer surfaces 55 of the polymer substrate 52 selected for plating may be prepared to receive a catalyst by mechanical abrasion or chemical etching. According to a next block 68, a catalyst layer may be deposited on the prepared outer surface(s) 55 of the polymer substrate and the exposed surfaces of the interlocking apertures 59 and/or the crevices 60 according to a next block 68, as shown. The catalyst layer may have a thickness on the atomic scale and may consist of palladium or another suitable catalyst material. It is noted that, if desired, masking may be used during the metal deposition steps (blocks 68, 70, 72, and 74) to prevent attachment of the metal plating 54 to certain outer surfaces of the polymer substrate.

According to a next block 70, electroless (or current-free) deposition of a first layer, which may be nickel, on the catalyst layer may be performed as will be understood by those having ordinary skill in the art. Following the block 70, electrolytic deposition of a second layer on the first layer may then be performed according to a block 72, as shown. The second layer may be a copper layer or another conductive material, such as silver or conductive graphite. Following the electrolytic deposition of the second layer, the outer surface(s) 55 of the polymer substrate 52 (including the coated surfaces of the interlocking apertures 59 and/or the crevices 60) may exhibit surface characteristics similar to a metal (i.e., conductivity), thereby allowing the deposition of additional metal platings thereon. Accordingly, the metal plating 54 may be then be deposited on the second layer (including the coated surfaces of the interlocking apertures 59 and/or the crevices 60) according to the block 74, as shown. The metal plating layer 54 may be deposited by a metal deposition technique apparent to those having ordinary skill in the art including, but not limited to, electroplating, electroless plating, and electroforming. During the block 74, the interlocking apertures 59 and/or the crevices 60 may be filled with the metal plating 54. Optionally, additional metal plating layers having the same or different compositions may be deposited by repeating the block 74 as desired. Following the block 74, the plated polymer component 50 having interlocking features 57 which may markedly enhance the interfacial strength between the metal plating 54 and the polymer substrate 52 is provided.

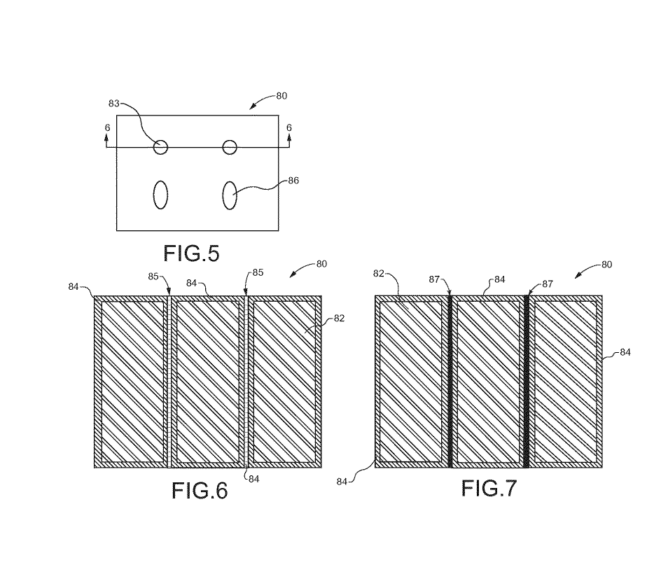

Turning now to FIGS. 5-6, an alternative interlocked plated polymer component 80 is shown. The interlocked plated polymer component 80 may be a structural or operative component for use in a gas turbine engine or in another application requiring lightweight and high-strength parts. Furthermore, as will be understood by those of ordinary skill in the art, the interlocked plated polymer component 80 may have any structure suitable for its practical use and, therefore, may deviate substantially from the exemplary box-like structure shown in FIG. 5. For example, it may have curved surfaces, asymmetric surfaces, and/or internal passages. The component 80 may consist of a polymer substrate 82 having one or more metal platings 84 deposited on its exposed surfaces, as best shown in FIG. 6. The metal plating 84 may substantially increase the structural robustness of the component 80.

The component 80 may exhibit high interfacial bond strength between the metal plating 84 and the polymer substrate 82 by virtue of one or more interlocking holes 85 which may extend through the entire body of the polymer substrate 82, as best shown in FIG. 6. More specifically, the interlocking holes 85 may resist the bulk separation of the metal plating 84 from the polymer substrate 82 as the separation would require the shear failure of the metal plating 84 and/or the polymer substrate 82 through the interlocking holes 85 in addition to the outer surface(s). Notably, the number, location, and distribution pattern of the interlocking holes 85 throughout the body of the polymer substrate 82 may be designed according to the application and structural requirements of the component 80. For example, the component 80 may have one or several interlocking holes 85 which may be localized to certain regions of the polymer substrate 82 or may be evenly distributed in a repeating or random pattern throughout the body of the substrate. They may be circular holes 83 or rounded slots 86 as shown in FIG. 5.

The metal plating 84 may consist of any platable material such as, but not limited to, nickel, cobalt, copper, iron, gold, silver, palladium, rhodium, chromium, zinc, tin, cadmium, and alloys with any of the foregoing elements comprising at least 50 wt. % of the alloy, and combinations thereof. The thickness of the metal plating 84 may be in the range of about 0.001 inches (0.0254 mm) to about 0.050 inches (1.27 mm), but other metal plating thicknesses may also apply. The polymer substrate 82 may be formed from a thermoplastic or thermoset material. Suitable thermoplastic materials may include, but are not limited to, polyetherimide (PEI), thermoplastic polyimide, polyether ether ketone (PEEK), polyether ketone ketone (PEKK), polysulfone, polyamide, polyphenylene sulfide, polyester, polyimide, and combinations thereof. Suitable thermoset materials may include, but are not limited to, condensation polyimides, addition polyimides, epoxy cured with aliphatic and/or aromatic amines and/or anhydrides, cyanate esters, phenolics, polyesters, polybenzoxazine, polyurethanes, polyacrylates, polymethacrylates, silicones (thermoset), and combinations thereof. Optionally, the polymeric material of the polymer substrate 82 may be structurally reinforced with one or more materials that may include carbon, metal, or glass.

As an optional arrangement, one or more of the interlocking holes 85 may be filled with a filling agent 87, as shown in FIG. 7. Such an arrangement may be favorable, for example, when solid outer surfaces of the component 80 are desired. The filling agent 87 may be an epoxy material, an epoxy material containing a metal filler, a low-melting alloy, a physical plug, or another type of filling agent chosen by a skilled artisan. If an epoxy material containing a metal filler is employed as the filling agent 87, the metal fillers may act to mitigate differences between the coefficient of thermal expansion (CTE) of the metal plating 84 (which lines the walls of the interlocking holes 85) and the filling agent 87, such that the metal plating 84 and the filling agent 87 may expand and contract similarly in response to temperature fluctuations. In this regard, the use of low-melting alloys as the filling agent 87 may also be desirable to provide metal-to-metal bonding contacts between the metal alloy filling agent 87 and the metal plating 84, while also providing suitable CTE matching between the filling agent 87 and the metal plating 84. A suitable low-melting metal alloy may be, but is not limited to, a tin-bismuth alloy. Suitable physical plugs as the filling agent 87 may be, but are not limited to, wires which may be press-fit into the interlocking holes 85 or introduced by another method. It is also noted that the outer surfaces of the component 80 may be smoothed, if desired, after filling the interlocking holes 85 with the filling agent 87.

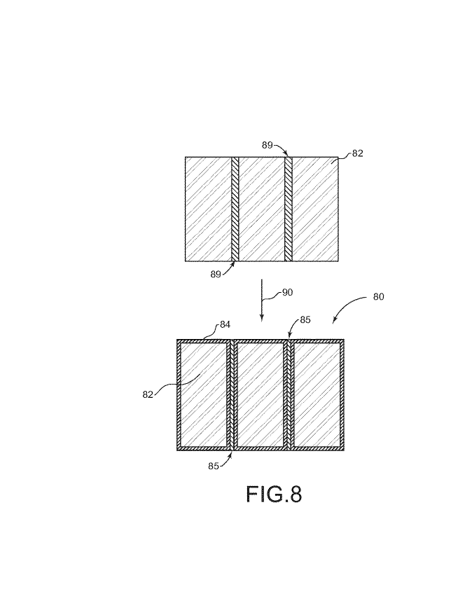

The fabrication of the component 80 is schematically depicted in FIG. 8. First, the polymer substrate 82 may be formed into a desired shape by a method apparent to those of ordinary skill in the art such as, but not limited to, injection molding, compression molding, blow molding, additive manufacturing (liquid bed, powder bed, deposition process), or composite layup (autoclave, compression, or liquid molding) as a neat resin or with fiber reinforcement (e.g., carbon fibers or glass fibers). If injection molding or additive manufacturing is used to form the polymer substrate, one or more holes 89 may be directly introduced into the body of the polymer substrate during the forming of the polymer substrate 82. Alternatively, the holes 89 may be introduced into the polymer substrate 82 following formation using a technique apparent to those of ordinary skill in the art such as, but not limited to, machining, drilling, or etching.

Depending on the method used for depositing the metal plating 84 (electroless plating, electroplating, electroforming, etc.), the holes 89 may have a minimum diameter of about 0.063 inches (about 1.6 mm) for electroplating or a minimum diameter of about 0.031 inches (about 0.8 mm) for electroless plating, but other hole diameters may also suffice. Electroplating may require larger hole diameters as it may be difficult to pass sufficient current density through smaller holes during the electrolytic process and provide uniform metal deposition. The holes 89 of the polymer substrate 82 may have different diameters and may or may not be oriented perpendicular to the outer surfaces of the polymer substrate 82 (i.e., they may be oriented at oblique angles with respect to the outer surfaces of the polymer substrate 82).

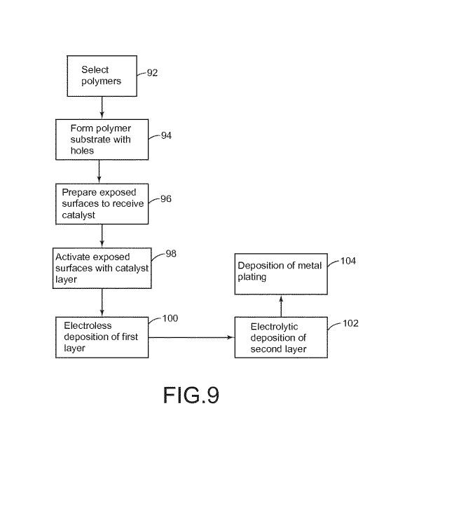

After the polymer substrate 82 is formed, the metal plating 84 may be introduced onto selected exposed surfaces of the polymer substrate 82 as well as the walls of the holes 89. In this regard, masking of selected surfaces of the polymer substrate 82 may be used to block certain exposed surfaces from being plated, if desired. Plating of the metal on the exposed surfaces of the polymer substrate 82 may be achieved following suitable polymer surface activation and metallization (see FIG. 9 and further details below) by a plating process 90 apparent to those of ordinary skill in the art including, but not limited to, electroless plating, electroplating, and electroforming. Electroless plating may involve the current-free deposition of a metal layer on the polymer substrate in a solution containing the desired metal ions and one or more reducing agents. In contrast, electroplating may be achieved in the presence of a current whereby the polymer substrate 82 may be connected to an electrical circuit as a cathode and the anode may be formed from a metal of the desired metal plating composition. The polymer substrate 82 may then be placed in an electrolytic bath containing metal ions of the desired metal(s) and a current may be applied to cause the deposition of reduced metal ions on the exposed surfaces of the polymer substrate.

For electroplating in holes 89 that have an aspect ratio (hole depth/diameter) greater than three (3), one or more supplemental anodes may be employed to assist uniform plating along the walls of the holes 89. The supplemental anodes may insert into the holes 89 during the electrolytic process to help provide uniform plating coverage. The supplemental anodes may be formed from the metal of the desired plating and may be conformal anodes having a shape that mirrors the shape of the holes 89. Depending on the number of holes in the polymer substrate 82, the supplemental anodes may be connected to each other to form a single comb-like structure having supplemental anodes as prongs which insert into each of the holes 89 during electrolytic deposition. However, those of ordinary skill in the art will understand that depending on the number, size, and arrangement of the holes 89, various other supplemental anode arrangements may be employed for electrolytic metal plating. Following the plating process 90, the component 80 having interlocking holes 85 may be provided, as shown.

A method for forming the interlocked plated polymer component 80 is illustrated further detail in FIG. 9. According to a first block 92, polymeric materials and optional reinforcing fibers for forming the polymer substrate 82 may be selected from the thermoset polymers, thermoplastic polymers, and optional reinforcing fibers listed above. According to a next block 94, the polymer substrate 82 having a desired shape and with one or more holes 89 may be formed from the selected polymer materials (and optional reinforcing fibers) using the forming techniques described above (i.e., injection molding, compression molding, blow molding, additive manufacturing, composite layup, etc.). Alternatively, the polymer substrate may be formed without holes and have holes introduced in a separate step by a conventional method, such as drilling. Blocks 96, 98, 100, 102, and 104 illustrate procedures which may be involved in the deposition of the metal plating 84 on selected exposed surfaces of the polymer substrate 82. If desired, metal plating deposition on certain exposed surfaces of the polymer substrate 82 may be prevented with the use of masking techniques well-known in the industry during these blocks.

The selected exposed surfaces (including the walls of the holes 89) of the polymer substrate 82 may first be prepared to receive a catalyst according to a block 96, as shown. Preparation of the selected exposed surfaces may involve surface etching, surface abrasion, ionic activation, or another suitable method selected by a skilled artisan. According to a next block 98, the exposed surfaces of the polymer substrate 82 (including the walls of the holes 89) may be activated with a catalyst layer, which may be a palladium catalyst layer having a thickness on the atomic scale. As other non-limiting possibilities, the catalyst may be platinum or gold. Electroless deposition of a first layer on the catalyst layer followed by electrolytic deposition of a second layer on the first layer may be performed by the blocks 100 and 102, respectively. The first layer may be formed from nickel. The second layer may be copper or another suitable conductive material, such as silver or conductive graphite. Following the deposition of the second layer, the surfaces of the polymer substrate 82 may exhibit surface properties similar to a metal (e.g., conductivity), thereby allowing the subsequent deposition of one or more metal plating layers thereon. According to a next block 104, deposition of the metal plating 84 on the second layer may be performed by a metal deposition method apparent to those skilled in the art including, but not limited to, electrolytic deposition (electroplating), electroless deposition, or electroforming. It is noted that the electrolytic deposition of the second layer and the metal plating 84 in the holes 89 may be achieved with the use of supplemental anodes, particularly for holes having an aspect ratio greater than three, as described above. Following the block 104, additional plating layers having the same or different compositions may be deposited by electroplating or by another plating technique apparent to those of ordinary skill in the art.

### INDUSTRIAL APPLICABILITY

From the foregoing, it can therefore be seen that introduction of mechanical interlocking features at the interface of metal platings and polymer substrates in plated polymer structures may advantageously enhance the interfacial bond strength between the metal plating and the polymer substrate. The technology as disclosed herein may be particularly applicable in industries requiring high-strength and lightweight materials, such as, but not limited to, automotive, aerospace, and sporting industries.

What is claimed is:

1. A plated polymer component, comprising:
a polymer substrate having an outer surface;
a metal plating attached to the outer surface of the polymer substrate; and
at least one interlocking feature connecting the polymer substrate and the metal plating.

2. The plated polymer component of claim 1, wherein the at least one interlocking feature comprises an interlocking aperture formed on the outer surface of the polymer substrate that is filled with a material of the metal plating.

3. The plated polymer component of claim 2, wherein the plated polymer component comprises a plurality of the at least one interlocking features.

4. The plated polymer component of claim 3, wherein the interlocking aperture is formed on the outer surface of the polymer substrate by a method selected from the group consisting of additive manufacturing, injection molding, and machining.

5. The plated polymer component of claim 1, wherein the at least one interlocking feature comprises a crevice formed on the outer surface of the polymer substrate that is filled with a material of the metal plating.

6. The plated polymer component of claim 5, wherein the crevice is formed on the outer surface of the polymer substrate by micro-knurling.

7. The plated polymer component of claim 1, wherein the at least one interlocking feature comprises at least one interlocking hole extending through a body of the polymer substrate, and wherein the at least one interlocking hole includes a hole extending through the body of the polymer substrate that is plated along a wall of the hole with the metal plating.

8. The plated polymer component of claim 7, wherein the hole is formed through the body of the polymer substrate by a method selected from the group consisting of injection molding, additive manufacturing, machining, drilling, and etching.

9. The plated polymer component of claim 8, wherein the at least one interlocking hole is filled with a filling agent.

10. A plated polymer component, comprising:
a polymer substrate having at least one exposed surface;
a metal plating deposited on the at least one exposed surface of the polymer substrate; and
at least one interlocking hole extending through a body of the polymer substrate, the at least one interlocking hole including a hole extending through the body of the polymer substrate that is plated along a wall of the hole with the metal plating.

11. The plated polymer component of claim 10, wherein the metal plating is plated on the wall of the hole by electrolytic deposition.

12. The plated polymer component of claim 11, wherein the hole has a diameter of at least about 1.6 mm.

13. The plated polymer component of claim 10, wherein the metal plating is plated on the wall of the hole by electroless deposition.

14. The plated polymer component of claim 13, wherein the hole has a diameter of at least about 0.8 mm.

15. The plated polymer component of claim 10, wherein the at least one interlocking hole is filled with a filling agent.

16. The plated polymer component of claim 15, wherein the filling agent is selected from the group consisting of an epoxy material, an epoxy material containing a filler metal, a low-melting alloy, and one or more wires.

17. A plated polymer component, comprising:
a polymer substrate having an outer surface;
a metal plating attached to the outer surface of the polymer substrate; and
a plurality of interlocking features at an interface between the metal plating and the polymer substrate, each of the plurality of interlocking features consisting of an interlocking aperture formed on the outer surface of the polymer substrate that is filled with a material of the metal plating.

18. The plated polymer component of claim 17, wherein the interlocking aperture is formed on the outer surface of the polymer substrate by a method selected from the group consisting of additive manufacturing, injection molding, and machining.

19. The plated polymer component of claim 18, wherein the interlocking aperture has a depth of at least about 0.005 mm.

20. The plated polymer component of claim 17, wherein at least one of the plurality of interlocking apertures comprises a crevice formed on the outer surface of the substrate that is filled with a material of the metal plating.
